(19) United States
(12) Patent Application Publication
(10) Pub. No.: US 2005/0138500 A1
(43) Pub. Date: Jun. 23, 2005

(54) Functional test design for testability (DFT) and test architecture for decreased tester channel resources

(76) Inventors: Chimsong Sul, Mountain View, CA (US); Fidel Muradali, Mountain View, CA (US)

Correspondence Address: AGILENT TECHNOLOGIES, INC.;Intellectual Property Administration, Legal Department, DL 429, P.O. Box 7599, Loveland, CO, 80537-0599, US

(21) Appl. No.: 10/721,474

(22) Filed: Nov. 25, 2003

(51) Int. Cl. G01R 31/28

(52) U.S. Cl. 714/724

(57) ABSTRACT

According to one aspect of the present invention, multiple pins of a chip are connected to a single test channel of a tester. This allows an older tester with fewer test channels to be used with newer chips that have more pins than there are test channels.

In testing semiconductor integrated digital circuits or chips, an ideal situation would be that any device under test (DUT), which is the chip being tested, has the same number of pins or less as the number of test channels on a tester. A single test channel on a tester is typically dedicated to a single pin on the DUT. As the pin count of chips increases, a manufacturer is faced with the dilemma of either buying new and more expensive test equipment to handle chips with more pins, or of finding some way to use existing testers having fewer test channels. For example, an older model tester would have from 256 to 350 test channels that would effectively test a 256 to 350 pin chip. However, newer chips and thus newer testers can have anywhere from 512 to 2000 channels and some newer routing network processor chips have over 2000 pins.

Therefore, a problem exists to find a way to test a 2000 pin chip with a 300 channel tester. Using prior art techniques, this is impossible because, as stated above, each test channel usually is dedicated to one pin on the chip. One prior solution to this problem is to provide multiple scan paths inside the chip having their inputs connected to a single pin. Referring to FIG. 1, it is common to test errors on a DUT 1 using scan path technique. Typically, there are a number of scan paths 4 within the DUT 1, each scan path 4 receiving an input data signal ID via an input pin 2 and input logic 3, and producing an output data signal OD via output logic 6 to an output pin 8. A tester (not shown) typically shifts data into the scan path 4 serially through the input pin 2. The DUT 1 is clocked and performs some kind of processing on the data, and then the processed data is shifted out through the output pin 8 and analyzed. Generally, the scan path technique is that data on internal nodes can be latched and shifted out to make sure that those nodes have the expected data based upon the input data. Therefore, scan path testing is effectively an internal probing of the DUT 1.

One problem with conventional scan path testing is that two pins are needed for each scan path 4, one input pin 2 and one output pin 8. Therefore, the number of pins on the DUT 1 limits the possible number of scan paths 4. Referring again to FIG. 1, another problem is the need for the multiplexer 7 on the output side of the scan path 4. The multiplexer 7 selects between the scan output data signal OD during scan test and the functional output data signal FO from a functional circuit 5 during normal operation. The multiplexer 7 introduces a delay that may cause a problem or limit performance during the normal mode operation.

Another alternative is to use decompression on the chip so as to convert a small string of data into a large string of data for testing the chip. For example, suppose there are 5 scan channels in the chip expecting 60 bits of data each. One could use a decompression algorithm to take these 300 bits and compress them down into a smaller number of bits, for example 10 bits. Then, the tester can input these 10 bits into a single pin of the chip, and these bits can be stored in a register and then decompressed into the three hundred bits that are needed to be input to the 5 scan paths (60 bits for each path). Again, doing this on the chip uses chip resources that could otherwise be used for functional circuits on the chip. A similar compression scheme on the output of the chip can be used to reduce the number of output pins that need to be read by the tester. That is, one can compress the test data on the chip and provide the compressed data on fewer pins of the chip, but this once again uses valuable chip resources.

Referring again to FIG. 1, another type of test that is performed on semiconductor chips is a functional test that tests actual functioning of the circuit 5 under test conditions. A tester (not shown) provides data to the functional circuit 5 via input pin 2, input logic 3, and the functional input signal FI. The functional circuit 5 processes the data and passes the functional output signal FO through the output logic 6, and on to the output pin 8. The tester (not shown) then analyzes the data.

Referring to FIG. 2, in semiconductor testing “compaction” is a technique used to reduce the number of output bits that need to be analyzed during a test function. The compactor 9 consists of a number of serially connected cyclic shift register cells CSRC that form a cyclic shift register 12. Typically, scan input data signals SID are shifted into a number of scan chains 10 and then the scan output data signals SOD from these scan chains are gated with compactor feedback data signals CFD from the cyclic shift register cells CSRC. Each cyclic shift register cell CSRC receives gated input from an XOR gate 11. When all the scan output data has been shifted through the cyclic shift register 12, the value retained in the cyclic shift register has a known value which can be shifted out and analyzed as a compacted output data signal COD. For example, one can shift in 1000 bits through the cyclic shift register 12 that may only have 20 cyclic shift register cells CSRC. Therefore, instead of having to analyze and compare all 1000 bits to a known bit pattern, one only need compare the final 20 bits from the compaction cyclic shift register 12 to the known bit pattern.

Referring again to FIG. 2, although not a problem per se with compaction, much of the data that is input to the compaction cyclic shift register 12 is of a don't care nature. That is, some of the compacted output data COD is non-deterministic meaning that one cannot predict its value based on the value of the scan input data SID. Therefore, in order to allow compaction to work, i.e., so that an unknown value doesn't give an unknown result, the don't care data values need to be masked. Referring to FIG. 3, this is done with logic for each individual cyclic shift register cell 17 of the cyclic shift register 12 (FIG. 2). This logic is part of the same circuit as the cyclic shift register 12 (FIG. 2). The mask signal mask and the scan output data signal SOD are gated with an AND gate 16 before being input to the individual cyclic shift register cell 17. By changing the value of the mask signal mask, one can mask the scan output data signal SOD for a given clock cycle. Consequently, the output cell-out of the individual cyclic shift register cell 17, is no longer of a don't care nature.

There is a need for testing chips having a large number of pins with testers having fewer test channels than pins on the chip.

### SUMMARY

According to one aspect of the present invention, multiple pins of a chip are connected to a single test channel of a tester. This allows an older tester with fewer test channels to be used with newer chips that have more pins than there are test channels.

### BRIEF DESCRIPTION OF THE DRAWINGS

FIG. 1 is a block diagram of a conventional scan test and functional integrated circuit.

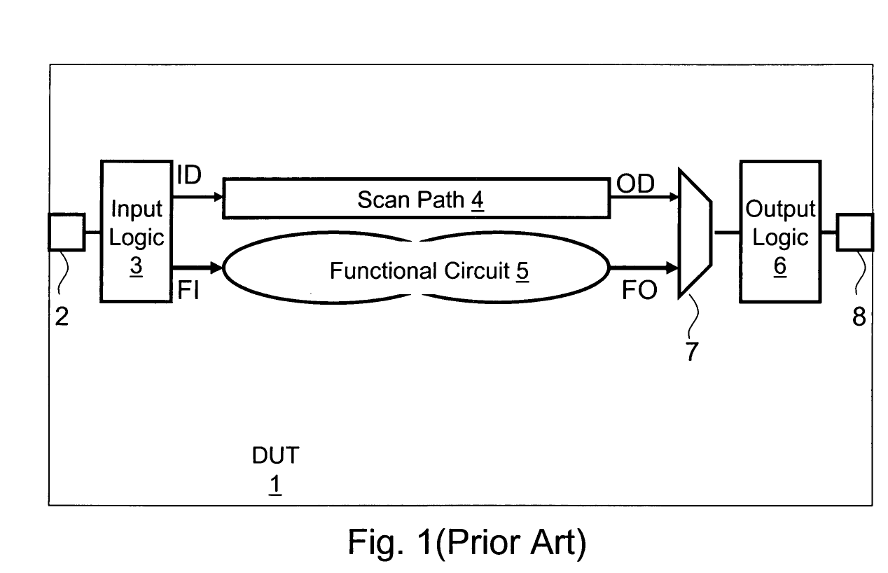

FIG. 2 is a block diagram of a conventional compactor with scan chain input.

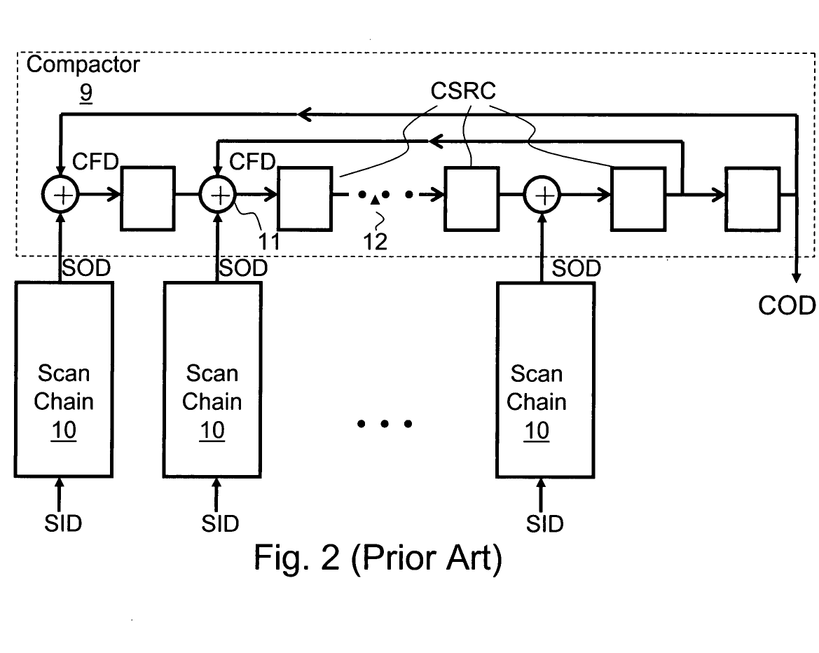

FIG. 3 is a logic diagram of components used in a conventional compaction test to eliminate don't care values.

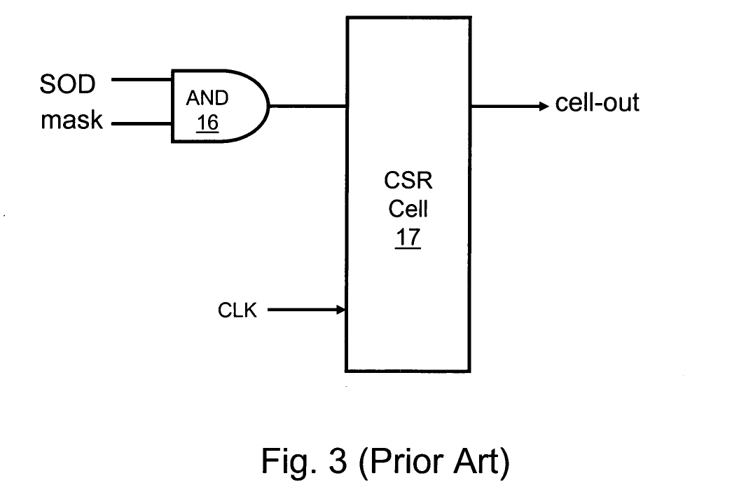

FIG. 4 is a block diagram of a test system utilizing a test management unit according to an embodiment of the invention.

FIG. 5 is a block diagram of regions and observability feedback register cells in the DUT of FIG. 4 according to an embodiment of the invention.

FIG. 6 is a schematic logic diagram of an observability feedback register cell of FIG. 5 according to an embodiment of the invention.

FIG. 7 is a detailed logic diagram with control signals of the observability feedback register cell of FIG. 6 according to an embodiment of the invention.

FIG. 8 is a block diagram of a compactor with the observability feedback register cell logic of FIG. 7 according to an embodiment of the invention.

FIG. 9 is a block diagram of an observability feedback register made up of the observability cells of FIG. 5 with parallel output according to an embodiment of the invention.

FIG. 10 is a block diagram of an observability feedback register with serial output according to an embodiment of the invention.

FIG. 11 is a logic diagram of logic used to eliminate bi-directional I/O and don't cares during functional testing according to an embodiment of the invention.

FIG. 12 is a block diagram of a test system utilizing the test management unit of FIG. 4 as a test-bench according to an embodiment of the invention.

### DESCRIPTION OF THE INVENTION

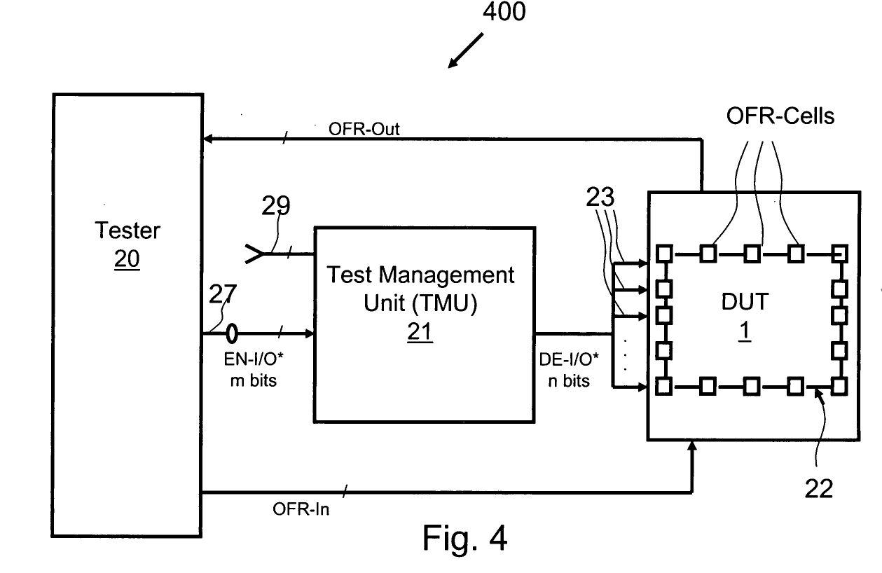

FIG. 4 is a functional block diagram of a test system 400 including a test management unit (TMU) 21, which may be formed from a Field Programmable Gate Array (FPGA), and which operates as a test pattern decoder to interface multiple chip pins 23 of a DUT 1 to a single test channel 27 of a tester 20 according to one embodiment of the present invention. Only one test channel 27 of the tester 20 is shown in FIG. 4, although the tester includes a number of such test channels coupled to the TMU 21. A compression-decompression scheme as previously discussed can be implemented on the TMU 21 such that the test channel 27 can input a relatively small number of bits and then the TMU can decompress the small number into a larger number of bits for input to multiple scan chains (not shown in FIG. 4) within the DUT 1. Specifically, m bits of an output-disabled-encoded-I/O signal EN-I/O* are fed to the TMU 21. The TMU 21 decodes the output-disabled-encoded-I/O signal EN-I/O* into n bits of an output-disabled-decoded-I/O signal DE-1/0*. Here, m<n<2**m+1. The n bits of the output-disabled-decoded-I/O signal DE-I/O* are then fed into respective scan chains within the DUT 1. In this way, each scan chain has its own unique pattern of input data defined by the corresponding nth bit of the DE I/O* signal.

The TMU 21 thus operates as test pattern decoder to decode test data in the form of the EN-I/O* signals from the tester 20 and thereby generate decoded test data in the form of the DE-I/O* signals that are applied to the DUT 1. The specific decoding algorithm executed by the TMU 21 may vary, and could, for example, include such common decoding algorithms as BIST, TestKompress, and DBIST, each of which will be understood by those skilled in the art. Moreover, because the TMU 21 is external to the DUT 1, the specific decoding algorithm executed need not be optimized, as is the case when the circuitry for executing the algorithm is contained in the DUT. The tester 20 or some other external circuit (not shown) applies configuration signals 29 to the TMU 21 to program or configure the TMU to execute the desired decoding algorithm. For example, where the TMU 21 is formed in a FPGA the configuration signals 29 include data, clock, and control signals to program the FPGA to execute the desired decoding algorithm.

The DUT 1 includes an observability feedback register (OFR) 22 composed of a number of serially-connected observability cells OFR-Cells that function as a compaction circuit. The tester 20 applies to the DUT 1 an OFR-input signal OFR-In including signals to control the OFR 22, such as a reset signal or signals corresponding to a reset signature to thereby to reset the contents of the OFR. After compaction of test results in the DUT 1, the contents of the OFR 22, which is called a signature, is output from the DUT as a signature signal OFR-Out to the tester 20.

In operation, the tester 20 initially applies the OFR-In signals to the DUT 1 to initialize the contents of the OFR 22, and also applies the EN-I/O* signals to the TMU 21 which, in turn, decodes these signals to develop the DE-I/O* signals that are applied the pins 23 of the DUT 1. During testing, the tester 20 applies required test data and control signals (not shown) to the DUT 1 to control the device as required, as will be appreciated by those skilled in the art. The tester 20 thereafter receives the OFR-Out signals from the DUT 1 and determines whether these signals indicate the DUT 1 is operating properly. Note that the OFR-Out signals of FIG. 4 are intended to indicate generally output from the DUT 1 to the tester 20 during testing, and are not limited to a signature being output from the OFR 22. For example, in functional testing of the DUT 1 the OFR 22 may not be used and in this situation the OFR-Out signals correspond to test data being supplied from the DUT I to the tester 20 for analysis to determine whether the DUT is operating properly.

In one embodiment, the tester 20 operates first in a scan test mode to perform a scan test on the DUT 1 and then operates in a functional test mode to perform a functional test on the DUT 1. In the scan mode, the TMU 21 is configured to couple desired groups of pins 23 of the DUT 1 to desired test channels 27 of the tester 20. The tester 20 also develops the OFR-In signals to initialize the OFR 22, and the tester and TMU 21 thereafter operate in combination to execute a scan test of the DUT 1. The results of the scan test are output from the DUT 1 as the OFR-Out signals, and the tester 20 determines from these signals whether the scan test indicates any defects exist in the DUT.

Once the scan test is completed, the scan mode terminates and operation in the functional test mode commences. In the functional test mode, the tester 20 and TMU 21 are reconfigured to execute the desired functional test on the DUT 1. Typically, such reconfiguration would include assigning a different correlation between the pins 23 of the DUT 1 and the test channels 27 of the tester 20. If the TMU 21 is implemented in an FPGA, then reconfiguration of the TMU can occur relatively easily, allowing for quickly switching between the scan and functional test modes of operation.

In another embodiment of the invention, the OFR-Out signal from the OFR 22 on the DUT 1, which corresponds to the signature from the OFR, is part of a functional test performed by the TMU 21 and tester 20.

Although the TMU 21 is shown as being external to the DUT 1 in FIG. 4, in another embodiment the TMU is formed inside the DUT 1 and not external to the DUT. This could be done, for example, where the TMU 21 is formed by an FPGA formed on the DUT 1. This would allow on-chip, meaning on the DUT 1, testing of the DUT while also allowing the tester 20 to program the TMU 21 to define the decoding algorithm being executed by the TMU.

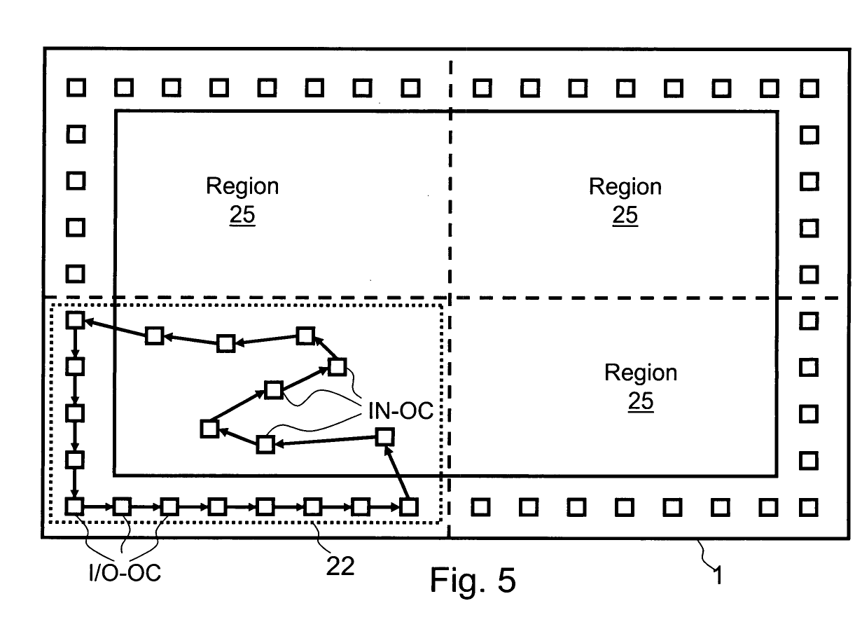

FIG. 5 is a functional diagram illustrating the layout and interconnection of internal observability cells IN-OC and peripheral or input output (I/O) observability cells I/O-OC in the DUT of FIG. 4 according to one embodiment of the present invention. The layout of the IN-OC, I/O-OC cells in the embodiment of FIG. 5 allows testing of the DUT I using a functional test mode in which not all pins 23 (FIG. 4) on the DUT are probed, and is useful when there are not enough tester channels 27 (FIG. 4) on the tester 20 (FIG. 4) for the number of pins 23 on the DUT 1. Instead of probing each pin 23 of the DUT 1, the functional behavior of components in the DUT 1 is determined by internally sampling signals present on input/output pins (not shown) of the DUT using the I/O-OC cells and by using the IN-OC cells formed in the DUT at specific locations to aid in indicating the operability of functional circuitry (not shown) in the DUT. The I/O-OC and IN-OC cells are connected in a linear fashion to form the OFR 22 of FIG. 4, which operates as a compaction circuit as will be discussed in more detail below. The DUT 1 is partitioned into test regions 25, with the I/O-OC and IN-OC interconnected to circuitry (not shown) within each test region to enhance the resolution of testing of the DUT. In operation, test data is transferred into the DUT 1 and applied to the functional circuitry within the DUT, and the test results data is then stored in the I/O-OC and IN-OC cells. This test results data is then serially transferred out of the I/O-OC cells to the tester 20 for detection of faults within the DUT.

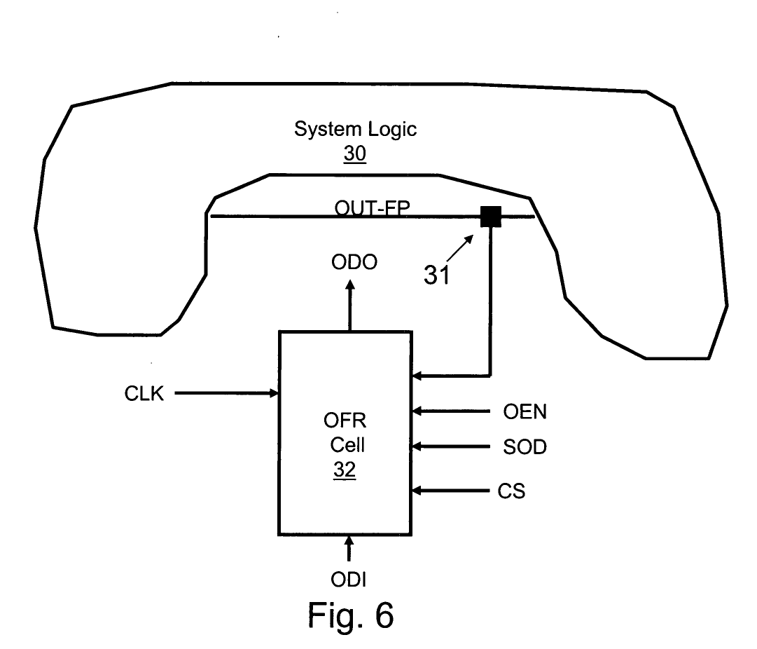

FIG. 6 is a schematic diagram illustrating in more detail one of the I/O-OC and IN-OC cells of FIG. 5 according to an embodiment of the invention. The I/O-OC and IN-OC cells are indicated generically as an OFR cell 32 in FIG. 6. The system logic 30 within the DUT 1 applies an output-functional-path signal OUT-FP on a test point 31, and this OUT-FP signal is applied to a first input of the OFR cell 32. A scan output data signal SOD is applied to a second input to the OFR cell 32 when scan chain testing is being done. The OFR cell 32 also receives output-data-in signal ODI from an adjacent serially connected cell (not shown) in the OFR 22 (FIG. 5) of which the illustrated OFR cell 32 is a part. In operation, the OFR cell 32 operates in a compaction mode or a shift mode to provide either OUT-FP, SOD, or the ODI signal as an output-data-out signal ODO, with the mode of operation being determined by an output enable signal OEN and a compaction signal CS. A clock signal CLK is applied to the OFR cell 32 to clock either the OUT-FP or ODI signal out as the ODO signal.

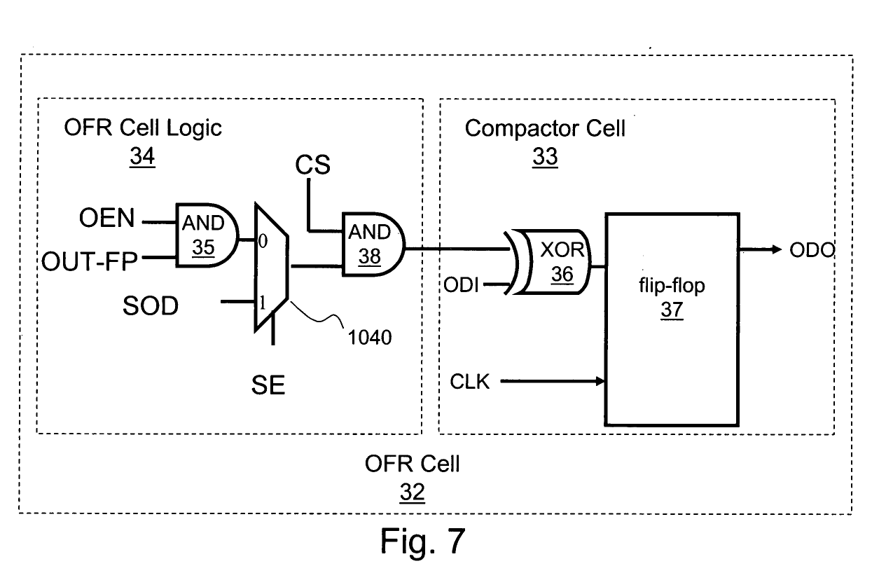

The OFR cell 32 operates in the compaction mode when the OEN signal is active and the CS signal is active. In the compaction mode, the OFR cell 32 performs a compacting function, such as an exclusive OR or XOR operation, on the OUT-FP signal or the scan output data signal SOD, with the cell latching the result of this XOR operation and providing this result as the ODO signal responsive to the CLK signal. The logic to choose the OUT-FP signal or the scan output data signal SOD is shown in FIG. 7 and is described below. The OFR cell 32 operates in the shift mode if either of the CS or OEN signals is inactive, and in the shift mode the cell latches the ODI signal and outputs this latched signal as the ODO signal responsive to the CLK signal. Thus, in the shift mode the OFR cell 32 functions as an individual cell in a conventional shift register, storing an output in the form of the ODI signal from an adjacent upstream cell and providing that output in the form of the ODO signal to the adjacent downstream cell. The CS signal may be viewed as placing the OFR cell 32 in either the compaction or shift mode of operation, with the OEN signal providing a further level of control of the cell to determine what whether the type of data—input or output—on the test point 31 is compacted.

FIG. 7 is a schematic illustrating in more detail one embodiment of the observability cell 32 of FIG. 6. The compactor cell 33 is prior art and the input signal to the compactor cell at any given time is selected by the OFR cell logic 34. The OEN signal is applied to enable an AND gate 35 which, when enabled, provides the OUT-FP signal from test point 31 (see FIG. 6) on an output. The output of the AND gate 35 is applied to a multiplexer 1040 which multiplexes the functional test data with the scan output data signal SOD. The scan enable signal SE applied to the multiplexer 1040 determines whether the scan test data or the functional test data is to be compacted. The output from the multiplexer 1040 is applied to an AND gate 38 which is enabled by the compact signal CS. The output of AND gate 38 is applied to an XOR gate 36 which performs the compaction function by generating an output signal which is the exclusive OR of the ODI signal and the signal from the AND gate 38. A flip-flop 37 latches the output from the XOR gate 36 responsive to the CLK signal and provides the latched signal as the ODO signal.

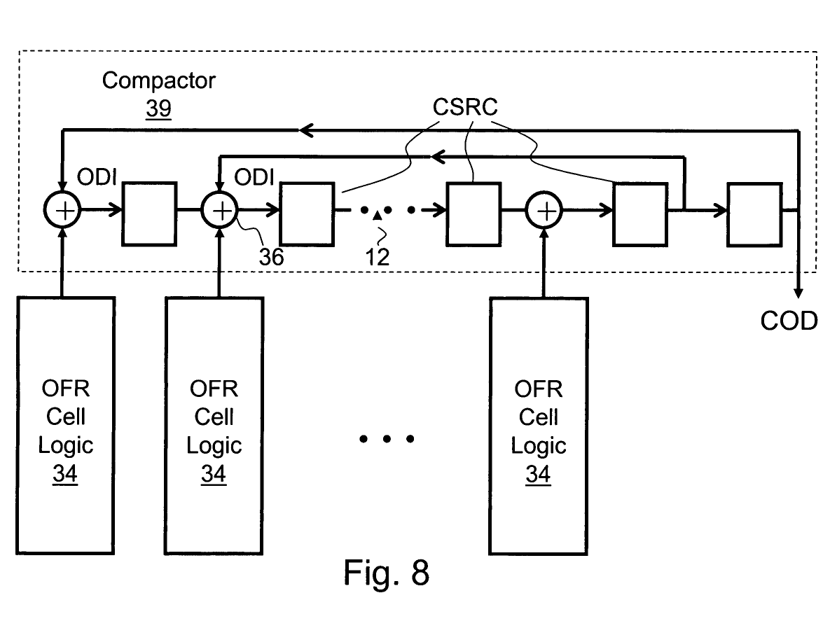

FIG. 8 is a diagram illustrating a compactor 9 made up of the OFR cells 32 of FIG. 7. The OFR cell logic 34 of FIG. 7 is applied to a series XOR gates 36 which feed a series of cyclic shift register cells CSRC that make up the cyclic shift register 12.

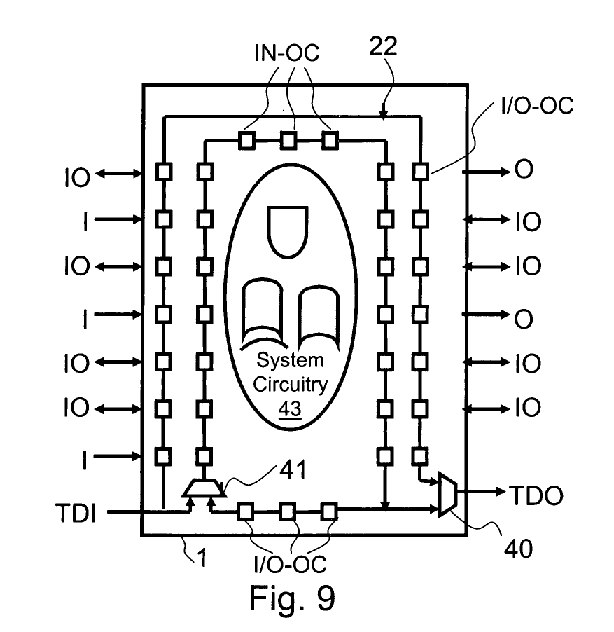

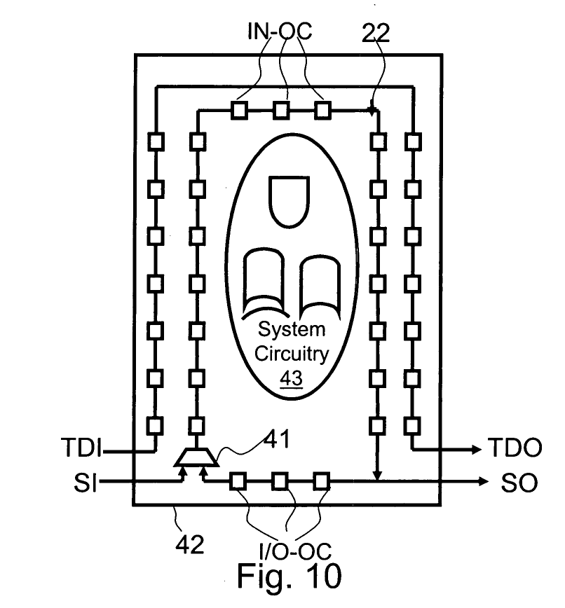

FIG. 9 is a functional block diagram illustrating in more detail one embodiment of the OFR 22 of FIG. 5. The OFR 22 includes boundary observability cells I/O-OC and internal observability cells IN-OC as previously discussed with reference to FIG. 5, and functions as a compaction circuit as will now be discussed in more detail. Test data is applied on input/output 10 and input only I pins designated in FIG. 8a and is transferred into the boundary observability cells I/O-OC. Output only pins O are also shown, and as previously discussed with reference to FIG. 7, the compaction function performed by the observability cells IN-OC, I/O-OC may be disabled depending on whether the cell is associated with an input or an output. In addition, a test data input signal TDI corresponds to test data that is shifted into the IN-OC cells through a feedback multiplexer 41 either from external to the DUT 1 containing the OFR 22 or from the I/O-OC cells. The test data transferred into the IN-OC and I/O-OC cells is processed by system circuitry 43 coupled to the cells to thereby test the system circuitry. After testing, the contents of the IN-OC and I/O-OC cells, which is the test signature, is shifted out as a test data out signal TDO. The content of the internal observability cells IN-OC is shifted out as a test data out signal TDO and the contents of the I/O-OC cells is also shifted out as a test data out signal TDO. Multiplexer 40 is used to determine the order and timing of the test data output signal TDO. FIG.10 is a functional block diagram illustrating another embodiment of the OFR 22 of FIG. 5. In this embodiment, test data corresponding to a test data in signal TDI is serially transferred into the boundary cells I/O-OC in contrast to the embodiment of FIG. 9 where data may be transferred in parallel into the I/O-OC cells.

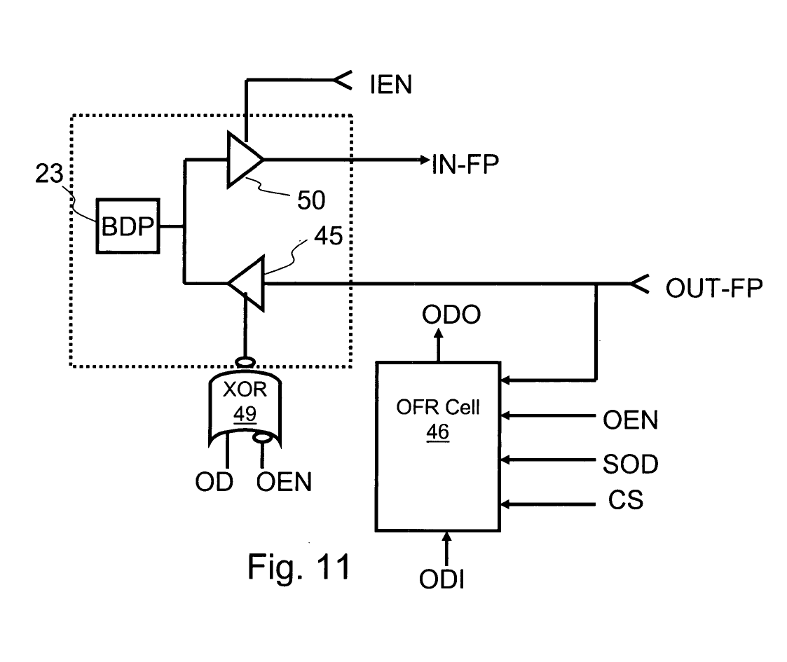

Referring to FIG. 11, a circuit for disabling an output of a bi-directional pin (BDP) 23 (see FIG. 4) of the DUT 1 is disclosed, and may be contained in the DUT according to one embodiment of the present invention. One problem when testing DUTs 1 with an excessive number of pins 23 is management of bi-directional I/O pins. Direction of operation of bi-directional I/O pins 23 is determined by a state of operation of the functional circuitry in the DUT 1, and is dynamic in nature. A BDP 23 is coupled to a data input buffer 50 and a data output buffer 45. The data input buffer 50 is controlled by an input-enable signal IEN, and operates to output a functional input signal IN-FP responsive to an input signal on the BDP 23 when the IEN signal is active, and goes into a high impedance state when the IEN signal is inactive. The data output buffer 45 is controlled by an output signal from a NOR-gate 49 fed by an output disable signal OD and the output-enable signal OEN. When either the OD signal is active high or the OEN signal is inactive low, the NOR gate 49 drives its output inactive low to thereby disable the data output buffer 45 which, in turn, goes into a high impedance state. If the OD signal is inactive low and the OEN signal is active high, the NOR gate 49 applies a high output to enable the data output buffer 45 which, in turn, provides a functional output signal OUT-FO on the BDP 23. In this way, the output disable signal OD may be activated to eliminate output from the BDP pin 23 in the form of the OUT-FP signal for the current clock cycle. The associated observability cell 32, which was previously discussed with reference to FIG. 6, also receives the functional output signal OUT-FO and operates as previously described responsive to the OEN and CS signals.

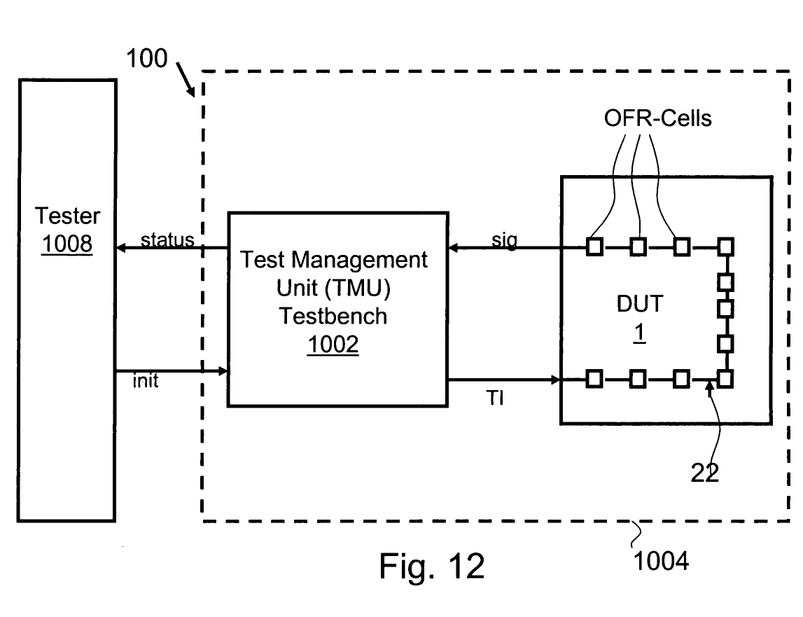

FIG. 12 is a functional block diagram illustrating a test system 1000 according to another embodiment of the invention. In the test system 1000, a test management unit (TMU 1002) and the DUT I operate as a test bench 1004 to verify that the test results from the DUT are accurate and then to send a status signal status to a tester 1008 indicating the status of the test results. As a result, the tester 1008 does not have to do the verification. In operation, the tester 1008 initializes the TMU 1002 with an initialization signal init, and the TMU thereafter uses a BIST type of program to generate a functional-test-input signal TI applied to the DUT 1. The DUT 1 processes the functional-test-input signal TI and, when finished, returns to the TMU a signature signal sig from the internal OFR 22 of the DUT 1. The TMU 1002 analyzes the signature signal sig and a status signal status is then sent to the tester 20 indicating the results of this analysis. This type of set up where the TMU 1002 and DUT I collectively form the test bench 1004 may be useful because when the TMU is an FPGA, the FPGA can run at clock rates that are near a clock rate of the DUT 1 (for example 500 mhz), while the tester 1008 may run at a significantly slower clock rate (for example 300 mhz). Therefore, under a conventional scenario the tester 1008 cannot test the DUT 1 at the intended operating speed of the DUT, which may affect the test results.

The preceding discussion is presented to enable a person skilled in the art to make and use the invention. Various modifications to the disclosed embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

1. A test circuit including at least one test channel input, each test channel input being adapted to receive respective encoded test channel data and the test circuit including configuration inputs adapted to receive configuration signals and further including a plurality of decoded outputs, the test circuit being programmable responsive to the configuration signals to execute a desired decoding algorithm, and being operable to apply the decoding algorithm to the encoded test channel data from each test channel input and to develop decoded test data, the decoded test data including N bits and the encoded test channel data including M bits, where N is greater than M, and the test circuit applying the decoded test data bits on the decoded outputs.

2. The test circuit of claim 1 wherein the test circuit comprises an FPGA.

3. The test circuit of claim 1 wherein the test circuit operates in a scan test mode and a functional test mode responsive to the configuration signals, and wherein the test circuit executes different decoding algorithms during the scan and functional test modes.

4. The test circuit of claim 3 wherein the test circuit couples each test channel input to a plurality of decoded outputs to define the decoding algorithm executed during the scan test mode.

5. The test circuit of claim 1 wherein M<N<2\hat{ }(M+1).

6. A test system, comprising:
a tester operable to provide encoded test channel data on at least one test channel output;
a test circuit including at least one test channel input, each test channel input being coupled to a corresponding test channel output to receive encoded test channel data and the test circuit including configuration inputs adapted to receive configuration signals and further including a plurality of decoded outputs, the test circuit being programmable responsive to the configuration signals to execute a desired decoding algorithm, and being operable to apply the decoding algorithm to the encoded test channel data from each test channel input and to develop decoded test data, the decoded test data including N bits and the encoded test channel data including M bits, where N is greater than M, and the test circuit applying the decoded test data bits on the decoded outputs; and
a device under test including circuitry and including a plurality of pins coupled to the circuitry, and at least some of the pins being coupled to the decoded outputs of the test circuit to receive decoded test data bits.

7. The test system of claim 6 wherein the test circuit comprises an FPGA.

8. The test system of claim 6 wherein the tester applies the configuration signals to the test circuit.

9. The test system of claim 6 wherein the test circuit operates in a scan test mode and a functional test mode responsive to the configuration signals, and wherein the test circuit executes different decoding algorithms during the scan and functional test modes.

10. The test system of claim 9 wherein the test circuit couples each test channel input to a plurality of decoded outputs to define the decoding algorithm executed during the scan test mode.

11. The test system of claim 6 wherein the test circuit is physically formed within the device under test, and wherein the test channel inputs and configuration inputs of the test circuit are coupled to pins of the device under test.

12. The test system of claim 11 wherein the test circuit operates in a scan test mode and a functional test mode responsive to configuration signals applied to corresponding pins of the device under test, and wherein the test circuit executes different decoding algorithms during the scan and functional test modes.

13. The test system of claim 6 wherein the tester further includes test data inputs and address and control outputs coupled to pins on the device under test, and wherein the develops signals on the address and control outputs to transfer decoded test data into the device under test via the test circuit, and wherein the device under test provides results test data on the test data inputs and the tester operates to analyze the test data to detect defects in the device under test.

14. The test system 6 wherein the test circuit and device under test collectively form a test bench, and wherein the tester provides an initialization signal to the test circuit on a test channel output and wherein, responsive to the initialization signal, the test circuit generates the configuration signals to execute the desired decoding algorithm and applies the decoded test data on the test channel inputs, the test circuit being further operable to apply address and control signals along with the decode test data to the device under test, wherein the device under test executes a test responsive to the address and control signals and decoded test data and applies a signature signal to the test circuit indicating the results of the test, and wherein the test circuit, responsive to the signature, processes the signature and applies a status signal to the tester indicating the results of the test.

15. The test system of claim 14 wherein the test circuit comprises an FPGA.

16. A method of testing a device under test having a plurality of pins M with a tester having a plurality of test channels N, where N is less than M, the method comprising:
coupling a plurality of pins on the device under test to the test channels on the tester;
transferring test data into the device under test over the test channels coupled to the pins on the device under test;
testing the device under test using the transferred test data; and
providing from the device under test an indication of the results of the test.

17. The method of claim 16 wherein testing the device under test using the transferred test data comprises executing a scan test in the device under test.

18. The method of claim 16 wherein providing from the device under test an indication of the results of the test comprises compacting internal test data within the device under test to generate a signature and providing the signature from the device under test.

19. A method of testing a device under test having a plurality of external pins M with a tester having a plurality of test channels N, where N is less than M, the method comprising:
applying test data on each of the test channels, the test data on each channel including X bits;
generating from the test data applied on each test channel expanded test data having Y bits, where Y is greater than X;
applying the respective bits of expanded test data on Y external pins of the device under test;
testing the device under test using the expanded test data applied on the pins; and
providing from the device under test an indication of the results of the test.

20. The method of claim 19 wherein generating from the test data applied on each test channel expanded test data and applying the respective bits of the expanded test data comprise:
during a scan test mode of operation,
generating expanded test data having a first group of Y bits;
applying the respective bits of expanded test data in the first group on a first group of Y external pins of the device under test;
during a functional test mode of operation,
generating expanded test data having a second group of Y bits;
applying the respective bits of expanded test data in the second group on a second group of Y external pins of the device under test.

21. The method of claim 20 wherein the first group of Y bits is different than the second group of Y bits and wherein the second group of Y external pins is the same as the first group of Y external pins.

22. The method of claim 19 wherein testing the device under test using the expanded test data applied on the pins comprises executing a scan test in the device under test.

23. The method of claim 19 wherein providing from the device under test an indication of the results of the test comprises compacting internal test data within the device under test to generate a signature and providing the signature from the device under test.
